(19) United States
(12) Patent Application Publication
(10) Pub. No.: US 2020/0105899 A1
(43) Pub. Date: Apr. 2, 2020

(54) Natural Uranium Oxide Gate Dielectric

(71) Applicant: Helen Krysta Harvin, Gainesville, FL (US)

(72) Inventor: Helen Krysta Harvin, Gainesville, FL (US)

(21) Appl. No.: 16/147,715

(22) Filed: Sep. 29, 2018

(51) Int. Cl. H01L 29/51

(52) U.S. Cl. CPC H01L 29/517

(57) ABSTRACT

A natural uranium oxide (NUO) gate dielectric forms a layer that separates a conductive gate electrode from an n-type or p-type semiconductor material. A natural uranium oxide (NUO) gate dielectric offers a higher dielectric strength than silicon dioxide (SiO2) gate dielectric materials in field-effect-transistors.

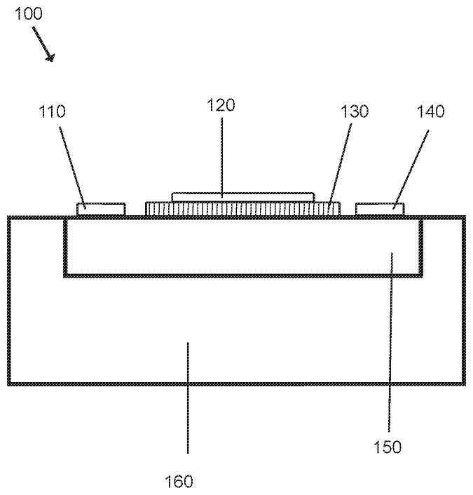

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### FIELD

The present invention generally relates to transistors, and more specifically, to field-effect-transistors utilizing natural uranium oxide (NUO) gate dielectric material.

### BACKGROUND OF THE INVENTION

Natural uranium oxide (NUO) is an abundant mineral found typically in uranium ore. Field-effect-transistors (FET) utilize gate dielectric materials with properties that may lead to dielectric breakdown and leakage by quantum tunneling. NUO gate dielectrics have superior electronic properties over silicon dioxide (SiO2) gate dielectric materials. As used herein, NUO refers to molecules including uranium of natural enrichment and oxygen of the form UxOy, where x=1-3 and y=1-8.

Employment of uranium oxide (e.g., UO2—also known as uranium dioxide) as a semiconductor material was initially proposed in the year 2000 by R. R. Price for depleted uranium waste utilization. See R. R. Price, M. J. Haire, and A. G. Croff, “Potential Uses of Depleted Uranium,” International Winter and Embedded Topical Meetings, Washington D.C. (Nov. 12-16, 2000). Electronic and optical properties of bulk polycrystalline and single crystalline UO2 were investigated, but no NUO gate dielectric has been reported.

### BRIEF SUMMARY OF THE INVENTION

Certain embodiments of the present invention may provide solutions to the problems and needs in the art that have not yet been fully identified, appreciated, or solved by conventional gate dielectric technologies. For example, some embodiments of the present invention pertain to gate dielectrics in field-effect-transistors including natural uranium oxide (NUO) gate dielectric.

In an embodiment, an apparatus includes a conductive gate electrode being placed adjacent to or affixed to and being separated by a NUO gate dielectric from an n-type or p-type semiconductor material placed adjacent to or affixed to the NUO gate dielectric.

### BRIEF DESCRIPTION OF THE DRAWING

In order that the advantages of certain embodiments of the invention will be readily understood, a more particular description of the invention briefly described above will be rendered by reference to a specific embodiment that is illustrated in the appended drawing. While it should be understood that this drawing depicts only typical embodiments of the invention and are not therefore to be considered to be limiting of its scope, the invention will be described and explained with additional specificity and detail through the use of the accompanying drawing, in which:

The drawing is a side view illustrating a natural uranium oxide (NUO) gate dielectric in a field-effect-transistor, according to an embodiment of the present invention.

### DETAILED DESCRIPTION OF THE INVENTION

Some embodiments of the present invention pertain to field-effect-transistors including natural uranium oxide (NUO) gate dielectric. Electrically isolating properties of NUO gate dielectrics make them excellent candidates for exploitation in field-effect-transistors. The dielectric constant of natural uranium dioxide (NUO2) at ˜22 is nearly double that for silicon dioxide (SiO2).

The drawing is a side view illustrating a field-effect-transistor 100 utilizing a NUO gate dielectric 130, according to an embodiment of the present invention. The NUO gate dielectric field-effect transistor (FET) 100 includes a source type metal electrode 110 (e.g., aluminum (Al), silver (Ag), gold (Au), etc.), a drain type metal electrode 140 (e.g., aluminum (Al), silver (Ag), gold (Au), etc.), a conductive gate electrode 120 (e.g., aluminum (Al), a highly doped silicon, silicide, etc.), a NUO dielectric 130, an n-type semiconductor material 150 and a p-type semiconductor substrate 160.

The NUO dielectric 130 may have thicknesses of a few nanometers to a millimeter in some embodiments. Source type metal electrode 110 may have a thickness of a few nanometers to a few hundred nanometers in some embodiments. Drain type metal electrode 140 may have a thickness of a few nanometers to a few hundred nanometers in some embodiments. The conductive gate electrode 120 may have thicknesses of a few nanometers to a millimeter in some embodiments. The p-type semiconductor substrate 160 may have thicknesses of a few nanometers to a centimeter in some embodiments. The n-type semiconductor material 150 may have thicknesses of a few nanometers to a few hundred nanometers in some embodiments.

The NUO dielectric 130 electrically insulates the conductive gate electrode 120 from the n-type semiconductor material 150. The n-type semiconductor material 150 and a p-type substrate 160 form a p/n junction. Operation as a field-effect-transistor is achieved when a positive voltage is applied to the conductive gate electrode 120. The electrically isolating properties of the NUO dielectric 130 allows an electric field to form from the conductive gate electrode 120 to the p-type semiconductor substrate 160. Electrons diffuse into the n-type semiconductor material 150 and lower electrical resistance between the source type metal electrode 110 and the drain type metal electrode 140.

It will be readily understood that the components of various embodiments of the present invention, as generally described and illustrated in the drawing herein, may be arranged and designed in a wide variety of different configurations. Thus, the detailed description of the embodiment of the system, apparatus and method of the present invention, as represented in the attached drawing, is not intended to limit the scope of the invention as claimed, but is merely representative of selected embodiments of the invention.

The features, structures, or characteristics of the invention described throughout this specification may be combined in any suitable manner in one or more embodiments. For example, reference throughout this specification to “certain embodiments,” “some embodiments,” or similar language means that a particular feature, structure, or characteristic described in connection with the embodiment is included in at least one embodiment of the present invention. Thus, appearances of the phrases “in certain embodiments,” “in some embodiment,” “in other embodiments,” or similar language throughout this specification do not necessarily all refer to the same group of embodiments and the described features, structures, or characteristics may be combined in any suitable manner in one or more embodiments.

It should be noted that reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

One having ordinary skill in the art will readily understand that the invention as discussed above may be practiced with steps in a different order, and/or with hardware elements in configurations which are different than those which are disclosed. Therefore, although the invention has been described based upon this preferred embodiment, it would be apparent to those of skill in the art that certain modifications, variations, and alternative constructions would be apparent, while remaining within the spirit and scope of the invention. In order to determine the metes and bounds of the invention, therefore, reference should be made to the appended claims.

1. An apparatus, comprising:
a dielectric material separating a conductive electrode from an n-type semiconductor material, wherein the dielectric material comprises natural uranium oxide (NUO).

2. The apparatus of claim 1, further comprising:
a p-type semiconductor material adjacent to or affixed to the n-type material, forming a p/n junction.

3. The apparatus of claim 2, wherein the n-type semiconductor material and the dielectric material are sufficiently thin to allow an electric field to pass through the p/n junction between the n-type semiconductor material and the p-type semiconductor material.

4. An apparatus, comprising:
a dielectric material separating a conductive electrode from a p-type semiconductor material, wherein the dielectric material comprises natural uranium oxide (NUO).

5. The apparatus of claim 4, further comprising:
an n-type semiconductor material adjacent to or affixed to the p-type material, forming a p/n junction.

6. The apparatus of claim 5, wherein the p-type semiconductor material and the dielectric material are sufficiently thin to allow an electric field to pass through the p/n junction between the p-type semiconductor material and the semiconductor n-type material.
